(19) United States
(12) Patent Application Publication
(10) Pub. No.: US 2025/0105232 A1
(43) Pub. Date: Mar. 27, 2025

(54) PHOTONIC IC CHIP, OPTICAL DEVICE AND SEMICONDUCTOR PACKAGE

(71) Applicant: Samsung Electronics Co., Ltd., Suwon-si (KR)

(72) Inventor: Youngbae Kim, Suwon-si (KR)

(21) Appl. No.: 18/806,017

(22) Filed: Aug. 15, 2024

(30) Foreign Application Priority Data
Sep. 21, 2023 (KR) 10-2023-0126517

(51) Int. Cl. H01L 25/16; G02B 6/125; G02B 6/42; H01L 23/00; H01L 23/498

(52) U.S. Cl. CPC H01L 25/167; G02B 6/125; G02B 6/423; G02B 6/424; H01L 23/49816; H01L 23/49827; H01L 24/16; H01L 2224/16227

(57) ABSTRACT

A photonic IC chip includes an optical waveguide including an entrance waveguide extending in a first direction, a first branch waveguide and a second branch waveguide respectively branched from the entrance waveguide, a concave reflector between the first branch waveguide and the second branch waveguide and having a first reflective surface and a second reflective surface, a first exit waveguide extending from the first branch waveguide in the first direction, and a second exit waveguide extending from the second branch waveguide in the first direction, wherein the first reflective surface is adjacent the first branch waveguide and the second reflective surface is adjacent the second branch waveguide. The first reflective surface reflects a first optical signal into the second branch waveguide, and the second reflective surface reflects a second optical signal into the first branch waveguide.

### RELATED APPLICATIONS

This application claims priority under 35 U.S.C. § 119 to Korean Patent Application No. 10-2023-0126517, filed on Sep. 21, 2023, in the Korean Intellectual Property Office (KIPO), the contents of which are herein incorporated by reference in their entirety.

### BACKGROUND

### 1. Field

Example embodiments relate to a photonic integrated circuit (IC) chip, an optical device and a semiconductor package. More particularly, example embodiments relate to a photonic IC chip having a waveguide for transmitting an optical signal, an optical device including the same and a semiconductor package including the same.

### 2. Description of the Related Art

In co-packaged optics (CPO) in which a semiconductor chip and an optical module for optical communication are integrated into a single package, a waveguide may be required for communication between chips. In this case, a Y-type optical waveguide with a gentle slope of a branch line may be used to branch a single signal while maintaining a signal intensity. However, there is a problem in that the Y-type optical waveguide with the gentle branch line slope increases an overall package size.

### SUMMARY

Example embodiments provide a photonic IC chip providing a waveguide having a relatively short extension length in a vertical direction.

Example embodiments provide an optical device including the photonic IC chip.

Example embodiments provide a semiconductor package including the photonic IC chip.

According to example embodiments, a photonic IC chip includes a substrate having a first surface and a second surface opposite the first surface; a front insulation layer on the first surface of the substrate and including a first material having a first index of refraction; and an optical waveguide in the front insulation layer and including a second material having a second index of refraction greater than the first index of refraction, wherein the optical waveguide includes an entrance waveguide extending in a first direction; a first branch waveguide and a second branch waveguide respectively branched from the entrance waveguide and symmetrically extending with respect to an extended central line of the entrance waveguide; a concave reflector between the first branch waveguide and the second branch waveguide and having a first reflective surface and a second reflective surface symmetrically extending with respect to the extended central line of the entrance waveguide; a first exit waveguide extending from the first branch waveguide in the first direction; and a second exit waveguide extending from the second branch waveguide in the first direction, wherein the first reflective surface is adjacent the first branch waveguide and the second reflective surface is adjacent the second branch waveguide, wherein the first reflective surface is configured to reflect a first optical signal introduced from the entrance waveguide and to transmit the first optical signal into the second branch waveguide, and wherein the second reflective surface is configured to reflect a second optical signal introduced from the entrance waveguide and to transmit the first optical signal into the first branch waveguide.

According to example embodiments, an optical device includes a photonic IC chip including a substrate having a first surface and a second surface opposite the first surface, a front insulation layer on the first surface of the substrate and including a first material having a first index of refraction, and an optical waveguide in the front insulation layer and including a second material having a second index of refraction greater than the first index of refraction; and an electronic IC chip stacked on the front insulation layer being spaced apart from the optical waveguide in a first direction, and being electrically connected with the photonic IC chip, wherein the optical waveguide includes an entrance waveguide extending in the first direction, a first branch waveguide and a second branch waveguide respectively branched from the entrance waveguide and symmetrically extending with respect to an extended central line of the entrance waveguide, a concave reflector between the first branch waveguide and the second branch waveguide and having a first reflective surface and a second reflective surface symmetrically extending with respect to the extended central line, a first exit waveguide extending from the first branch waveguide in the first direction, and a second exit waveguide extending from the second branch waveguide in the first direction, wherein the first reflective surface is adjacent the first branch waveguide and the second reflective surface is adjacent the second branch waveguide, wherein the first reflective surface is configured to reflect a first optical signal introduced from the entrance waveguide and to transmit the first optical signal into the second branch waveguide, and wherein the second reflective surface is configured to reflect a second optical signal introduced from the entrance waveguide and to transmit the second optical signal into the first branch waveguide.

According to example embodiments, a semiconductor package includes a package substrate including a first mounting region and a second mounting region spaced from the first mounting region in a first direction; at least one of electronic device mounted on the first mounting region of the package substrate; a photonic IC chip mounted on the second mounting region of the package substrate, the photonic IC chip including a substrate having a first surface and a second surface opposite through vias the first surface, a front insulation layer on the first surface of the substrate and including a first material having a first index of refraction; and an optical waveguide in the front insulation layer and including a second material having a second index of refraction greater than the first index of refraction, and an electronic IC chip stacked on the front insulation layer, being spaced apart from the optical waveguide in a first direction, and being electrically connected with the photonic IC chip, wherein the optical waveguide includes an entrance waveguide extending in a first direction, a first branch waveguide and a second branch waveguide branched from the entrance waveguide and symmetrically extending with respect to an extended central line of the entrance waveguide, a concave reflector between the first branch waveguide and the second branch waveguide and having a first reflective surface and a second reflective surface symmetrically extending with respect to the extended central line, a first exit waveguide extending from the first branch waveguide in the first direction; and a second exit waveguide extending from the second branch waveguide in the first direction, wherein the first reflective surface is adjacent the first branch waveguide and the second reflective surface is adjacent the second branch waveguide, wherein the first reflective surface is configured to reflect a first optical signal introduced from the entrance waveguide and to transmit the first optical signal into the second branch waveguide, and wherein the second reflective surface is configured to reflect a second optical signal introduced from the entrance waveguide and to transmit the second optical signal into the first branch waveguide.

According to example embodiments, a semiconductor package may include a package substrate providing a first mounting region and a second mounting region, at least one of electronic device mounted on the first mounting region, a photonic IC chip mounted on the second mounting region and an electronic IC chip mounted on the photonic IC chip.

The photonic IC chip may include an optical waveguide and a front insulation layer surrounding the optical waveguide. The photonic IC chip may include an entrance waveguide, a plurality of branch waveguides respectively branched from the entrance waveguide and a concave reflector which is on a central portion where the plurality of branch-waveguides intersect. The concave reflector may reflect a plurality of optical signals introduced from the entrance waveguide toward the plurality of branch waveguides, respectively.

Accordingly, the concave reflector may allow the plurality of branch waveguides to have a sharp change in slope, so the optical waveguide may have a short length in the vertical direction, as a result, the size of the photonic IC chip and semiconductor package may be reduced.

### BRIEF DESCRIPTION OF THE DRAWINGS

FIG. 1 is a plan view illustrating a semiconductor package in accordance with example embodiments.

FIG. 2 is a cross-sectional view taken along the line A-A′ in FIG. 1.

FIG. 3A is a plan view illustrating an optical device of FIG. 1.

FIG. 3B is a cross-sectional view taken along the line B-B′ in FIG. 3A.

FIG. 4 is an enlarged cross-sectional view illustrating portion ‘C’ of FIG. 3B.

FIGS. 5 and 6 are enlarged views illustrating portion ‘D’ of FIG. 3A.

### DETAILED DESCRIPTION OF EXAMPLE EMBODIMENTS

Hereinafter, example embodiments will be explained in detail with reference to the accompanying drawings.

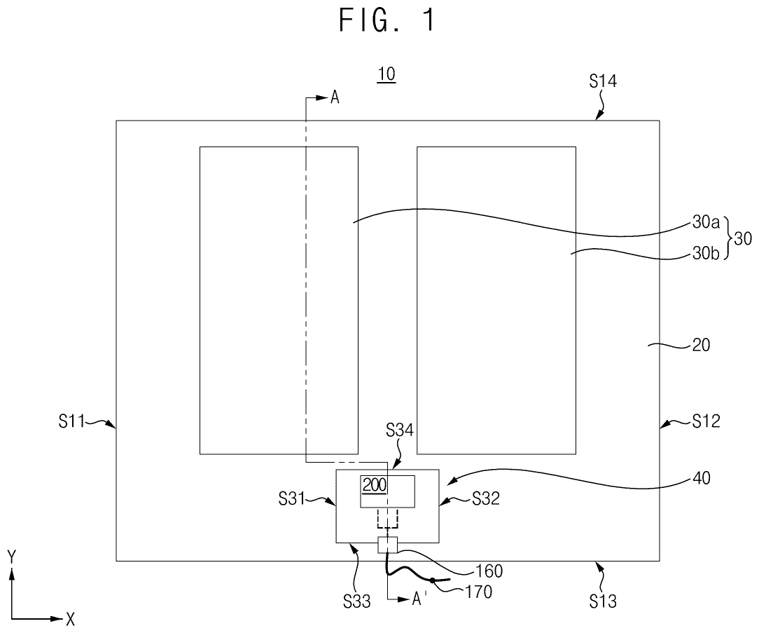

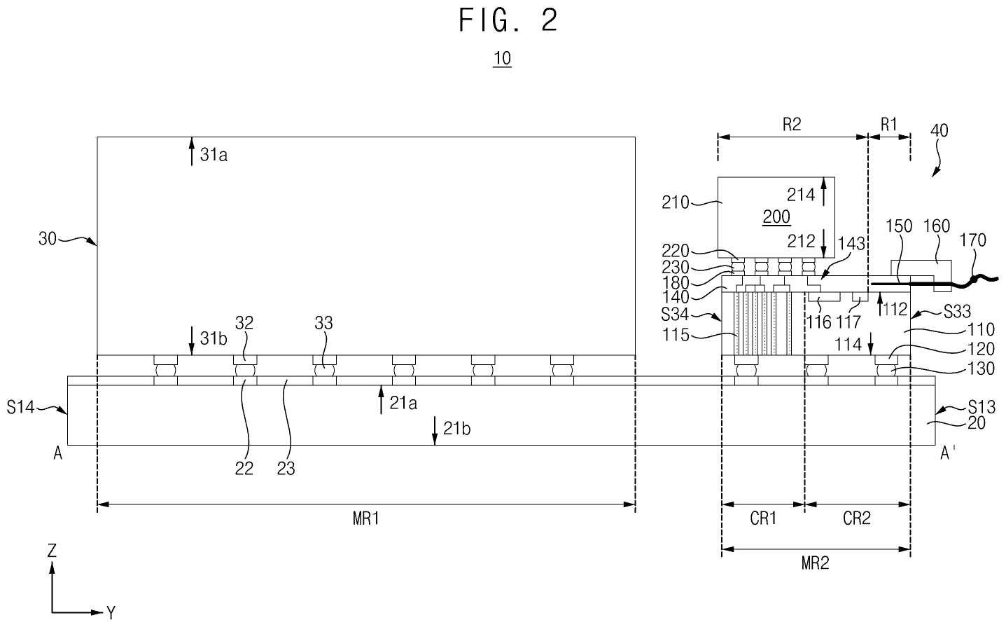

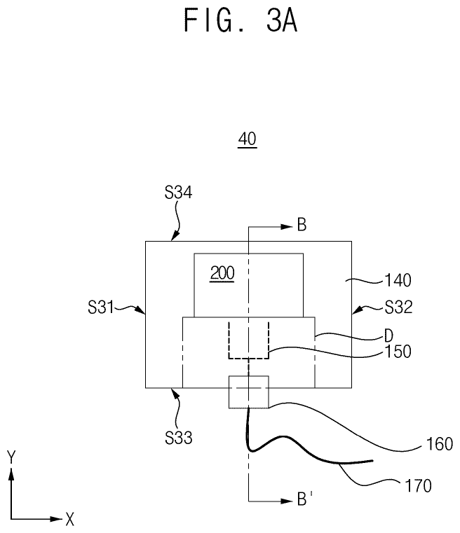

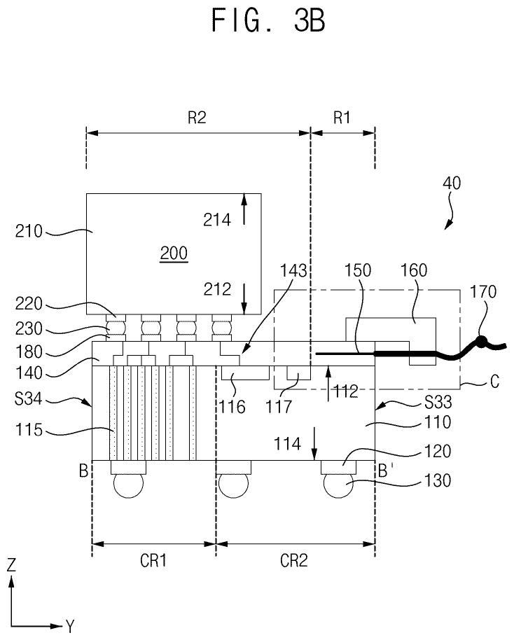

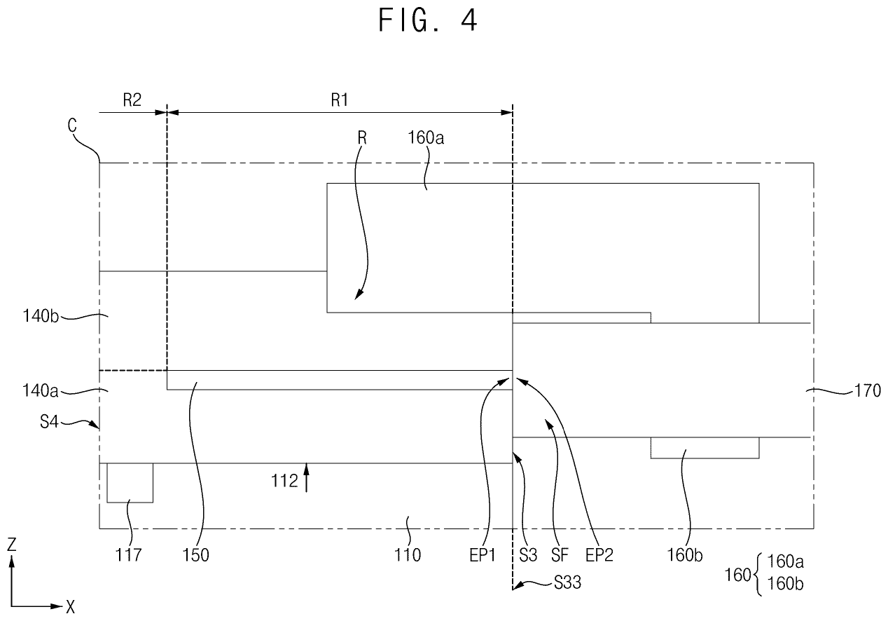

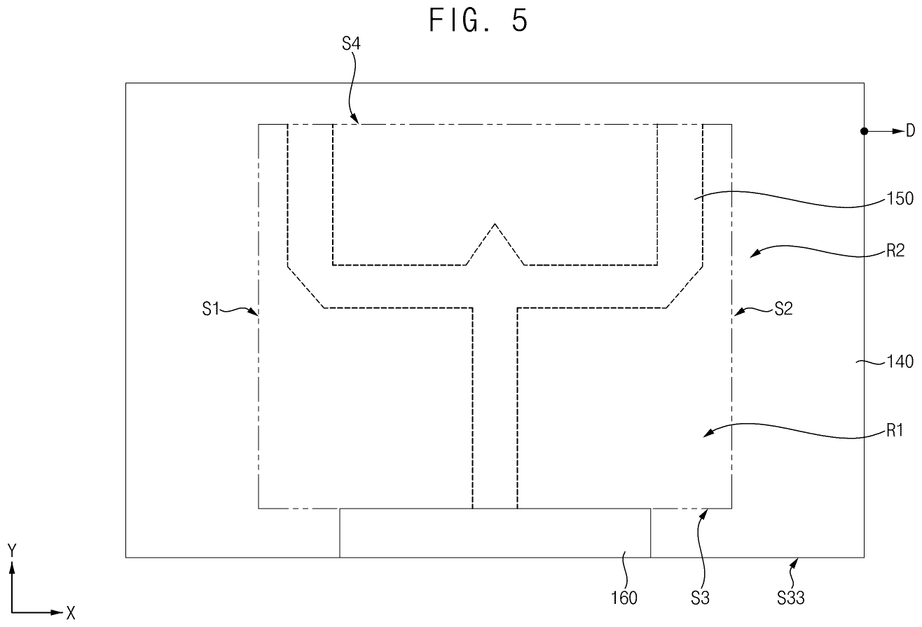

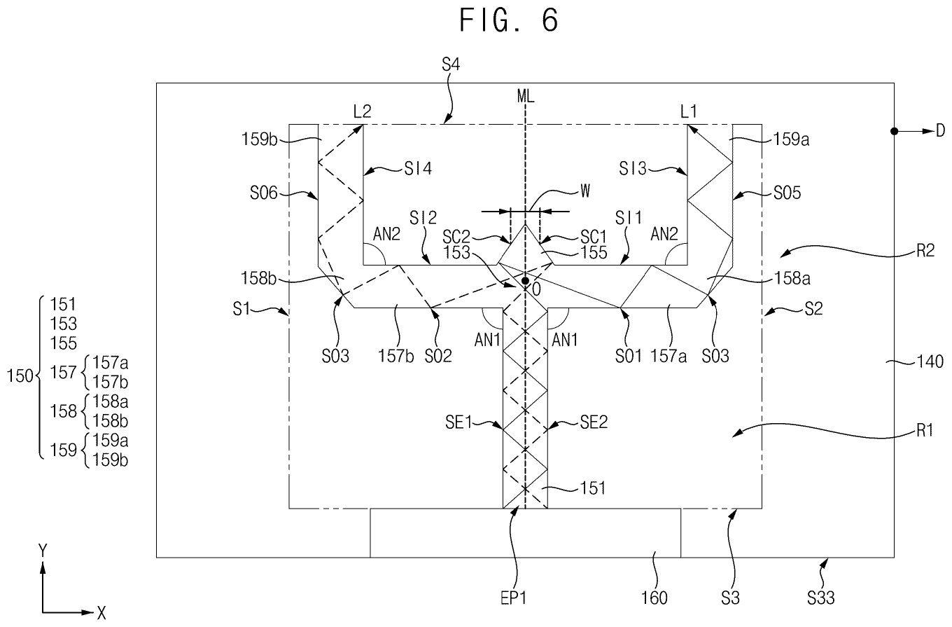

FIG. 1 is a plan view illustrating a semiconductor package in accordance with example embodiments. FIG. 2 is a cross-sectional view taken along the line A-A′ in FIG. 1. FIG. 3A is a plan view illustrating an optical device of FIG. 1. FIG. 3B is a cross-sectional view taken along the line B-B′ in FIG. 3A. FIG. 4 is an enlarged cross-sectional view illustrating portion ‘C’ of FIG. 3B. FIGS. 5 and 6 are enlarged views illustrating portion ‘D’ of FIG. 3B. FIG. 5 is a plan view illustrating an optical waveguide of a photonic IC chip in FIG. 1. FIG. 6 is a plan view illustrating a plurality of optical signals transmitted through the optical waveguide of FIG. 5.

Referring to FIGS. 1 to 6, a semiconductor package 10 may include a package substrate 20, at least one electronic device 30 stacked on the package substrate 20, and an optical device 40 stacked on the package substrate 20. The at least one electronic device 30 may further include a plurality of first conductive connection members 33 that are electrically connected with the package substrate 20. The optical device 40 may include a photonic IC chip 100 and an electronic IC chip 200 stacked on the photonic IC chip 100. The photonic IC chip 100 may further include a plurality of second conductive connection members 130 that are electrically connected with the package substrate 20. The photonic IC chip 100 may further include an optical fiber 170 that is configured to introduce an external optical signal and a coupler 160 that is configured to secure the optical fiber 170. The electronic IC chip 200 may further include a plurality of third conductive connection members 230 that are electrically connected with the photonic IC chip 100.

Additionally, the semiconductor package 10 may be co-packaged optics (CPO) that includes semiconductor chips and an optical module integrated into a single package. The semiconductor package 10 may include the at least one electronic device 30 as a memory chip. The at least one electronic device 30 may include a high bandwidth memory (HBM) device.

In example embodiments, the package substrate 20 may be a substrate having a first surface 21a and a second surface 21b facing each other. For example, the package substrate 20 may include a printed circuit board (PCB), a flexible substrate, a tape substrate, or the like. The printed circuit board may be a multilayer circuit board having vias and various circuits therein. The package substrate 20 may include internal wirings as channels for electrical connection with the at least one electronic device 30 and the photonic IC chip 100.

The package substrate 20 may include a first side portion S11 and a second side portion S12 extending in the first direction (Y direction) and facing each other, and a third side portion S13 and a fourth side portion S14 extending in the second direction (X direction) perpendicular to the first direction (Y direction) and facing each other.

The package substrate 20 may include at least one first mounting region MR1 adjacent the fourth side portion S14 and a second mounting region MR2 adjacent the third side portion S13. The first mounting region MR1 and the second mounting region MR2 may have a rectangular shape. The second mounting region MR2 may be spaced apart from the first mounting region MR1 along the first direction (Y direction).

The package substrate 20 may have a plurality of substrate pads 22 in the first mounting region MR1 and the second mounting region MR2, respectively. For example, the plurality of substrate pads 22 may be arranged in an array including a plurality of columns and rows in the first mounting region MR1 and the second mounting region MR2, respectively. The plurality of substrate pads 22 may be connected to the internal wirings, respectively. For example, at least a portion of the internal wiring may be provided as a substrate pad as a landing pad.

The package substrate 20 may include an insulation layer 23. The insulation layer 23 may be on the first surface 21a of the package substrate 20 and may expose the plurality of substrate pads 22. The insulation layer 23 may cover the entire first surface 21a of the package substrate 20 except for the plurality of substrate pads 22. For example, the insulation layer 23 may be on the first surface 21a. In some embodiments, the insulation layer 23 may include a solder resist.

Although only a few substrate pads are illustrated in the figures, it will be understood that the number, shape, and arrangement of the substrate pads are provided as an example, and the present inventive concept is not limited thereto.

In example embodiments, the at least one electronic device 30 may include a first electronic device 30a and a second electronic device 30b. The at least one electronic device 30 may be mounted on the first mounting region MR1 of the package substrate 20. For example, the first electronic device 30a and the second electronic device 30b may be sequentially positioned along the second direction (X direction) adjacent the fourth side portion S14 of the package substrate 20.

The at least one electronic device 30 may include at least one semiconductor chip. For example, the at least one electronic device 30 may include a high bandwidth memory (HBM) device including a plurality of semiconductor chips sequentially stacked.

The at least one electronic device 30 may have a first surface 31a and a second surface 31b opposite the first surface 31a. The at least one electronic device 30 may have a plurality of first chip pads 32 on the second surface 31b. The plurality of first chip pads 32 may be electrically connected to the plurality of semiconductor chips in the at least one electronic device 30. For example, the plurality of first chip pads 32 may be electrically connected with conductive through vias in each of the plurality of semiconductor chips.

The at least one electronic device 30 may further include the first conductive connection members 33. The at least one electronic device 30 may be mounted on the package substrate 20 via the first conductive connection members 33. For example, the first conductive connection members 33 may be respectively provided between the plurality of substrate pads 22 of the package substrate 20 and the plurality of first chip pads 32 of the at least one electronic device 30 to electrically connect the at least one electronic device 30 with the package substrate 20. For example, the first conductive connection members 33 may include solder bumps.

In example embodiments, the optical device 40 may be mounted on the second mounting region MR2 of the package substrate 20 and may be spaced from the at least one electronic device 30 along the second direction (Y direction). The optical device may be an optical engine including an optical chip and an electronic chip. The optical chip may convert external optical signals into electrical signals. The electronic chip may convert an analog signal, such as the electrical signals introduced from the optical chip into a digital signal. For example, the optical device may include a photonic integrated circuit (PIC) and an electronic integrated circuit (EIC).

The optical device 40 may include the photonic IC chip 100 and the electronic IC chip 200 stacked on the photonic IC chip 100.

In example embodiments, the photonic IC chip 100 may be mounted on the second mounting region MR2 of the package substrate 20 and may be spaced from the at least one electronic device 30 along the second direction (Y direction).

The photonic IC chip may include a photonic integrated circuit (PIC) that detects and transmits an optical signal, converts the optical signal into an electrical signal, and processes the electrical signal. The PIC may include laser diodes to generate optical signals, optical switches to manage paths of the optical signals, optical modulators to modulate the optical signals to transmit data, and photodetectors to convert the optical signals into electrical signals. For example, the photonic IC chip may convert an optical signal introduced from the optical fiber into an electrical signal.

The photonic IC chip 100 may include a first substrate 110, a plurality of through vias 115, a plurality of second chip pads 120, a front insulation layer 140, an optical waveguide 150, a coupler 160, an optical fiber 170, and a plurality of third chip pads 180. The photonic IC chip 100 may further include a plurality of electronic elements 116, a plurality of optical elements 117, and a plurality of wirings 143. The photonic IC chip 100 may further include the plurality of second conductive connection members 130.

The photonic IC chip 100 may be mounted on the package substrate 20 via the plurality of second conductive connection members 130. For example, the plurality of second conductive connection members 130 may be between the plurality of substrate pads 22 of the package substrate 20 and the plurality of second chip pads 120 of the photonic IC chip 100, respectively, to electrically connect the photonic IC chip 100 with the package substrate 20. For example, the plurality of second conductive connection members 130 may include solder bumps.

In example embodiments, the electronic IC chip 200 may be mounted on the front insulation layer 140 of the photonic IC chip 100. The electronic IC chip 200 may include a second substrate 210 and a plurality of fourth chip pads 220. The electronic IC chip 200 may further include the plurality of third conductive connection members 230.

For example, the electronic IC chip may be an electronic integrated circuit (EIC). For example, the EIC may convert an electrical signal in analog form that is introduced from the PIC into an electrical signal in digital form. Additionally, the EIC may be a semiconductor chip including electronic elements that convert an electrical signal of a current value into an electrical signal of a voltage value and amplify the converted electrical signal.

The electronic IC chip 200 may be mounted on the photonic IC chip 100 by a flip chip bonding method. For example, the electronic IC chip 200 may be mounted on the front insulation layer 140 via the plurality of third conductive connection members 230 that are between the plurality of third chip pads 180 and the plurality of fourth chip pads 220, respectively.

The second substrate 210 may have a front surface 212 and a backside surface 214 facing each other. For example, the plurality of fourth chip pads 220 may be arranged in an array along XY direction on the front surface 212 of the second substrate 210. For example, the plurality of fourth chip pads 220 may be conductive pads for electrical connections. For example, the electronic IC chip 200 may be mounted on the photonic IC chip 100 such that the front surface 212 on which the electronic elements are formed, as an active front surface 212 faces the photonic IC chip 100.

The plurality of third conductive connection members 230 may be on the plurality of fourth chip pads 220 respectively. For example, the plurality of third conductive connection members may be solder bumps including a metallic material.

Hereinafter, the optical device 40 of FIGS. 3A and 3B will be described.

Referring again to FIGS. 3A to 6, the optical device 40 may include the photonic IC chip 100 and the electronic IC chip 200 stacked on the photonic IC chip 100. The photonic IC chip 100 may further include the plurality of second conductive connection members 130 for electrical connection with an external device. The photonic IC chip 100 may further include the optical fiber 170 that is configured to introduce an external optical signal and a coupler 160 that is configured to secure the optical fiber 170. The electronic IC chip 200 may further include the plurality of third conductive connection members 230 for electrical connection with the photonic IC chip 100.

In example embodiments, the photonic IC chip 100 may include the first substrate 110, the plurality of through vias 115, the plurality of second chip pads 120, the plurality of second conductive connection members 130, the front insulation layer 140, the optical waveguide 150, the coupler 160, the optical fiber 170, and the plurality of third chip pads 180. The photonic IC chip 100 may further include the plurality of electronic elements 116, the plurality of optical elements 117, and the plurality of wirings 143.

The first substrate 110 may have a first surface 112 and a second surface 114 facing with each other. The first surface 112 of the first substrate 110 may be an active layer on which electronic elements 116 such as transistors are provided. Additionally, the optical elements 117 may be on the first surface 112 of the first substrate 110. The optical elements 117 may include the photonic integrated circuit (PIC) as described above.

The first substrate 110 may have a first side portion S31 and a second side portion S32 extending along a second direction (Y direction) and facing each other, and a third side portion S33 and a fourth side portion S34 extending along a first direction (X direction) perpendicular to the second direction (Y direction) and facing each other.

The first substrate 110 may have a first connector region CR1 in a region adjacent the fourth side portion S34 and a second connector region CR2 in a region adjacent the third side portion S33.

The plurality of through vias 115 may be in the first substrate 110 and may extend from the first surface 112 to the second surface 114. For example, the plurality of through vias 115 may include a conductive metallic material. For example, the plurality of through vias 115 may be in the first connector region CR1 of the first substrate 110 and may extend between the first surface 112 and the second surface 114.

The plurality of second chip pads 120 may be on the second surface 114 that is an inactive surface of the first substrate 110. For example, the plurality of second chip pads 120 may be on the second surface 114 of the first substrate 110 in an array including a plurality of columns and rows. For example, the plurality of second chip pads may be conductive pads. Portions of the plurality of second chip pads 120 may be electrically connected to the plurality of through vias 115.

The plurality of second conductive connection members 130 may be on the plurality of second chip pads 120 respectively and may be electrically connected with the plurality of second chip pads 120 respectively. For example, the plurality of second conductive connection members may be solder bumps including a conductive material. For example, the photonic IC chip 100 may be mounted on an interposer, a package substrate, etc. via the plurality of second conductive connection members.

The front insulation layer 140 may be on or cover the first surface 112, which is the active surface of the first substrate 110. The front insulation layer 140 may include a lower cladding portion 140a and an upper cladding portion 140b. The front insulation layer 140 may include a material with a relatively low refractive index. For example, the front insulation layer 140 may have a first index of refraction 21. For example, the front insulation layer 140 may include silicon dioxide (SiO₂).

The front insulation layer 140 may include a first region R1 in a region adjacent the third side portion S33 of the first substrate 110, and a second region R2 excluding the first region R1. The first region R1 may include first to fourth side portions S1, S2, S3 and S4. The first side portion S1 and the second side portion S2 may extend in a second direction (Y direction) and face with each other. The third side portion S3 and the fourth side portion S4 may extend in a first direction (X direction) and face with each other.

The front insulation layer 140 may have the plurality of wirings 143 in the second region R2 adjacent the fourth side portion S34 of the first substrate 110. The plurality of wirings 143 may be electrically connected with the plurality of through vias 115 and the plurality of electronic elements 116.

The optical waveguide 150 may be within the first region R1 of the front insulation layer 140. For example, the optical waveguide 150 may be between the lower cladding portion 140a and the upper cladding portion 140b. The optical waveguide 150 may include a material having a relatively high refractive index. For example, the optical waveguide 150 may have a second refractive index λ2 that is greater than the first refractive index λ1 of the front insulation layer 140. For example, the optical waveguide 150 may include silicon (Si).

The optical waveguide 150 may be a pathway through which light transmitted from the outside moves. For example, the plurality of optical signals that are introduced from the outside may be reflected by an interface between the optical waveguide 150 and the front insulation layer 140, and then, may be transmitted along the optical waveguide 150.

The coupler 160 may be on the front insulation layer 140 adjacent the third side portion S33 of the first substrate 110. For example, the coupler 160 may be on the first region R1 where the optical waveguide 150 is provided.

The coupler 160 may include a first portion 160a and a second portion 160b. The first portion 160a of the coupler 160 may be in a recess R that is adjacent the third side portion S3 of the first region R1, in the upper cladding portion 140b.

An end portion of the optical fiber 170 may be secured by the second portion 160b of the coupler 160 such that the optical fiber 170 is aligned with the optical waveguide 150. An external optical signal may be introduced through the optical fiber 170 into an entrance waveguide 151 of the optical waveguide 150.

For example, the optical waveguide 150 may have a first end portion EP1 that is exposed from a first side portion S3 of the front insulation layer 140. A central portion of the optical fiber 170 may have a second end portion EP2 that is exposed from an end portion SF of the optical fiber 170. The first end portion EP1 and the second end portion EP2 may be aligned in a line along the first direction (X direction).

The plurality of third chip pads 180 may be on the second region R2 of the front insulation layer 140 adjacent the fourth side portion S34 of the first substrate 110. For example, the plurality of third chip pads 180 may be on the front insulation layer 140 in an array including a plurality of columns and rows. For example, the plurality of third chip pads 180 may be conductive pads. The plurality of third chip pads 180 may be electrically connected to the plurality of wirings 143 within the front insulation layer 140.

In example embodiments, the electronic IC chip 200 may include the second substrate 210, the plurality of fourth chip pads 220, and the plurality of third conductive connection members 230. For example, the electronic IC chip may be an electronic integrated circuit (EIC) as described above.

The electronic IC chip 200 may be mounted on the front insulation layer 140 of the photonic IC chip 100 to be adjacent the fourth side portion S34 of the photonic IC chip 100. For example, the electronic IC chip 200 may be mounted on the photonic IC chip 100 by a flip chip bonding method. For example, the electronic IC chip 200 may be mounted on the front insulation layer 140 via the plurality of third conductive connection members 230 that are between the plurality of third chip pads 180 and the plurality of fourth chip pads 220, respectively. For example, the electronic IC chip 200 may be mounted on the photonic IC chip 100 such that the front surface 212 on which the electronic elements are formed as an active surface faces the photonic IC chip 100.

For example, the second substrate 210 may have the front surface 212 and the backside surface 214 facing with each other.

The plurality of fourth chip pads 220 may be arranged in an array along the XY direction on the front surface 212 of the second substrate 210. For example, the plurality of fourth chip pads 220 may be conductive pads for electrical connections.

The plurality of third conductive connection members 230 may be on the plurality of fourth chip pads 220, respectively. For example, the plurality of third conductive connection members may be solder bumps including a metallic material.

Hereinafter, the optical waveguide 150 of FIGS. 5 and 6 will be described.

In example embodiments, the optical waveguide 150 may include an entrance waveguide 151, a central portion 153, a concave reflector 155, a plurality of branch waveguides 157, a plurality of corner portions 158, and a plurality of exit waveguides 159.

The entrance waveguide 151 may extend in the first direction (Y direction). For example, the entrance waveguide 151 may extend along an extended centerline ML that passes through a center O of the central portion 153. For example, the entrance waveguide 151 may extend from the third side portion S3 of the first region R1 of the front insulation layer 140 to the central portion 153.

The entrance waveguide 151 may introduce a plurality of optical signals L1 and L2 into the optical waveguide 150 from the outside. For example, a first optical signal L1 and a second optical signal L2 may be introduced from the outside and transmitted from the entrance waveguide 151 to the central portion 153. The entrance waveguide 151 may provide a first extended reflective surface SE1 and a second extended reflective surface SE2 facing each other and extending in the first direction (Y direction).

The central portion 153 may be at a center of the first region R1 and may be a portion from which the plurality of branch waveguides 157 branch. The central portion 153 may be the portion where the entrance waveguide 151 and the plurality of branch waveguides 157 meet each other or intersect.

The concave reflector 155 may extend from the central portion 153 along the extended centerline ML by a predetermined distance. For example, the concave reflector 155 may extend from the central portion 153 toward the fourth side portion S4 of the first region R1 by the predetermined distance. Additionally, the concave reflector 155 may have a concave shape that is recessed in the second direction (Y direction) toward the fourth side portion S4.

The concave reflector 155 may have a plurality of reflective surfaces. For example, the concave reflector 155 may have a first reflective surface SC1 and a second reflective surface SC2 that face with each other.

The first reflective surface SC1 and the second reflective surface SC2 may be symmetrical about the extended centerline ML. A distance W between the first reflective surface SC1 and the second reflective surface SC2 may decrease as the central portion 153 approaches the fourth side portion S2. That is, a distance W between the first reflective surface SC1 and the second reflective surface SC2 decreases as the concave reflector 155 is further from an origin of the central portion 153.

The plurality of branch waveguides 157 may include a first branch waveguide 157a and a second branch waveguide 157b. The first branch waveguide 157a and the second branch waveguide 157b may branch from the entrance waveguide 151 and may be symmetrical to each other with respect to the extended centerline ML.

The first branch waveguide 157a may have a first outer reflective surface SO1 and a first inner reflective surface SI1 facing with each other, and the second branch waveguide 157b may have a second outer reflective surface SO2 and a second inner reflective surface SI2 facing with each other.

The first branch waveguide 157a may be branched from the entrance waveguide 151 such that the first outer reflective surface SO1 of the first branch waveguide 157a has a first angle AN1 with respect to the first extended reflective surface SE1, and the second branch waveguide 157b may be branched from the entrance waveguide 151 such that the second outer reflective surface SO2 of the second branch waveguide 157b has the first angle AN1 with respect to the second extended reflective surface SE2. The plurality of branch waveguides 157 may have a sharp change in slope. For example, the first angle may be 90 degrees. Accordingly, a vertical length of the optical waveguide 150 may be reduced. The vertical length may be a length of the optical waveguide 150 in the first direction (Y direction) in which the optical waveguide extends.

The plurality of optical signals L1 and L2 may be transmitted from the entrance waveguide 151 into the plurality of branch waveguides 157 via the reflective surfaces SC1 and SC2 of the concave reflector 155.

For example, the concave reflector 155 may be a structure for transmitting the plurality of optical signals L1, L2 introduced from the entrance waveguide 151 into the plurality of branch waveguides 157, respectively. For example, the first reflective surface SC1 may be adjacent the first branch waveguide 157a and may transmit the first optical signal L1 introduced from the entrance waveguide 151 into the second branch waveguide 157b. Additionally, the second reflective surface SC2 may be adjacent the second branch waveguide 157b and may transmit the second optical signal L2 introduced from the entrance waveguide 151 into the first branch waveguide 157a. For example, the first optical signal L1 may be introduced into the entrance waveguide 151 and the central portion 153 at an angle such that the first optical signal L1 is reflected by the second reflective surface SC2 into the first branch waveguide 157a. The second optical signal L2 may be introduced into the entrance waveguide 151 and the central portion 153 at another angle such that the second optical signal L2 is reflected by the first reflective surface SC1 into the second branch waveguide 157b.

The plurality of corner portions 158 may include a first corner portion 158a and a second corner portion 158b. The plurality of corner portions 158 may be in one end portions of the plurality of branch waveguides 157 respectively. For example, the first corner portion 158a may be in a first end portion of the first branch waveguide 157a opposite the central portion 153 and may include a third outer reflective surface SO3. Additionally, the second corner portion 158b may be in a first end portion of the second branch waveguide 157b opposite the central portion 153 and may have a fourth outer reflective surface SO4.

The plurality of exit waveguides 159 may include a first exit waveguide 159a and a second exit waveguide 159b. The plurality of exit waveguides 159 may extend from the first end portions of the plurality of branch waveguides 157 toward the fourth side portion S4 of the first region R1 in the first direction (Y direction).

The first exit waveguide 159a may have a fifth outer reflective surface SO5 and a third inner reflective surface SI3 facing with each other, and the second exit waveguide 159b may have a sixth outer reflective surface SO6 and a fourth inner reflective surface SI4 facing with each other.

The first exit waveguide 159a may be bent or inclined at the first corner portion 158a such that the third inner reflective surface SI3 of the first exit waveguide 159a has a second angle AN2 with respect to the first inner reflective surface SI1, the second exit waveguide 159b may be bent or inclined at the second corner portion 158b such that the fourth inner reflective surface SI4 of the second exit waveguide 159b has a second angle AN2 with respect to the second inner reflective surface SI2. The plurality of exit waveguides 159 may have a sharp change in slope. For example, the second angle may be 90 degrees. Accordingly, the vertical length of the optical waveguide 150 may be reduced. The vertical length may be a length of the optical waveguide 150 in the first direction (Y direction) in which the optical waveguide 150 extends.

As mentioned above, the semiconductor package 10 may include the package substrate 20, the at least one electronic device 30 mounted on the package substrate 20, and the optical device 40 mounted on the package substrate 20. Additionally, the optical device 40 may include the photonic IC chip 100 and the electronic IC chip 200 mounted on the photonic IC chip 100. Additionally, the photonic IC chip 100 may include the optical fiber 170 that is configured to introduce the external optical signal and the coupler 160 that is configured to secure the optical fiber 170.

The photonic IC chip 100 may include the optical waveguide 150 and the front insulation layer 140 surrounding the optical waveguide 150. The photonic IC chip 100 may include the entrance waveguide 151, the plurality of branch waveguides 157a and 157b branched from the entrance waveguide 151 and the concave reflector 155 that is on the central portion 153 where the plurality of branch waveguides 157a and 157b meet each other or intersect. The concave reflector 155 may reflect a plurality of optical signals L1 and L2 introduced from the entrance waveguide toward the plurality of branch waveguides 157a and 157b, respectively.

Thus, the concave reflector may allow the plurality of branch waveguides to have a sharp change in slope, so the optical waveguide may have a relatively short length in the vertical direction, as a result, the size of the photonic IC chip and semiconductor package may be reduced.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present inventive concept. Accordingly, all such modifications are intended to be included within the scope of example embodiments as defined in the claims.

What is claimed is:

1. A photonic IC chip, comprising:
a substrate having a first surface and a second surface opposite the first surface;
a front insulation layer on the first surface of the substrate and including a first material having a first index of refraction; and
an optical waveguide in the front insulation layer and including a second material having a second index of refraction greater than the first index of refraction,
wherein the optical waveguide includes,
an entrance waveguide extending in a first direction;
a first branch waveguide and a second branch waveguide respectively branched from the entrance waveguide and symmetrically extending with respect to an extended central line of the entrance waveguide;
a concave reflector between the first branch waveguide and the second branch waveguide and having a first reflective surface and a second reflective surface symmetrically extending with respect to the extended central line of the entrance waveguide;
a first exit waveguide extending from the first branch waveguide in the first direction; and
a second exit waveguide extending from the second branch waveguide in the first direction,
wherein the first reflective surface is adjacent the first branch waveguide and the second reflective surface is adjacent the second branch waveguide,
wherein the first reflective surface is configured to reflect a first optical signal introduced from the entrance waveguide and to transmit the first optical signal into the second branch waveguide, and
wherein the second reflective surface is configured to reflect a second optical signal introduced from the entrance waveguide and to transmit the second optical signal into the first branch waveguide.

2. The photonic IC chip of claim 1, wherein the concave reflector includes a central portion where the entrance waveguide, the first branch waveguide and the second branch waveguide intersect,
wherein a distance between the first reflective surface and the second reflective surface decreases as the concave reflector is further from an origin of the central portion.

3. The photonic IC chip of claim 1, wherein the entrance waveguide includes a first extended reflective surface and a second extended reflective surface that face each other and extend in the first direction,
wherein the first branch waveguide is branched from the entrance waveguide such that a first outer reflective surface of the first branch waveguide has a first angle with respect to the first extended reflective surface,
wherein the second branch waveguide is branched from the entrance waveguide such that a second outer reflective surface of the second branch waveguide has the first angle with respect to the second extended reflective surface.

4. The photonic IC chip of claim 3, wherein the first angle is 90 degrees.

5. The photonic IC chip of claim 1, wherein the first branch waveguide has a first inner reflective surface, and the second branch waveguide has a second inner reflective surface, and
wherein the first exit waveguide has a third inner reflective surface, and the second exit waveguide has a fourth inner reflective surface.

6. The photonic IC chip of claim 5, wherein the first exit waveguide is inclined from the first branch waveguide such that the first inner reflective surface has a second angle with respect to the third inner reflective surface, and
wherein the second exit waveguide is inclined from the second branch waveguide such that the second inner reflective surface has the second angle with respect to the fourth inner reflective surface.

7. The photonic IC chip of claim 6, wherein the second angle is 90 degrees.

8. The photonic IC chip of claim 1, further comprising:
a coupler on a side portion of the front insulation layer; and
an optical fiber secured by the coupler.

9. The photonic IC chip of claim 8, wherein a first end portion of the optical fiber is aligned with a second end portion of the entrance waveguide.

10. The photonic IC chip of claim 9, wherein the first optical signal and the second optical signal are introduced from the optical fiber into the entrance waveguide.

11. An optical device, comprising:
a photonic IC chip including a substrate having a first surface and a second surface opposite the first surface, a front insulation layer on the first surface of the substrate and including a first material having a first index of refraction, and an optical waveguide in the front insulation layer and including a second material having a second index of refraction greater than the first index of refraction, and
an electronic IC chip stacked on the front insulation layer, being spaced apart from the optical waveguide in a first direction, and being electrically connected with the photonic IC chip,
wherein the optical waveguide includes,
an entrance waveguide extending in the first direction;
a first branch waveguide and a second branch waveguide respectively branched from the entrance waveguide and symmetrically extending with respect to an extended central line of the entrance waveguide;
a concave reflector between the first branch waveguide and the second branch waveguide and having a first reflective surface and a second reflective surface symmetrically extending with respect to the extended central line;
a first exit waveguide extending from the first branch waveguide in the first direction; and
a second exit waveguide extending from the second branch waveguide in the first direction,
wherein the first reflective surface is adjacent the first branch waveguide and the second reflective surface is adjacent the second branch waveguide,
wherein the first reflective surface is configured to reflect a first optical signal introduced from the entrance waveguide and to transmit the first optical signal into the second branch waveguide, and
wherein the second reflective surface is configured to reflect a second optical signal introduced from the entrance waveguide and to transmit the second optical signal into the first branch waveguide.

12. The optical device of claim 11, wherein the entrance waveguide includes a first extended reflective surface and a second extended reflective surface facing each other and extending in the first direction,
wherein the first branch waveguide is branched from the entrance waveguide such that a first outer reflective surface of the first branch waveguide has a first angle with respect to the first extended reflective surface, and
wherein the second branch waveguide is branched from the entrance waveguide such that a second outer reflective surface of the second branch waveguide has the first angle with respect to the second extended reflective surface.

13. The optical device of claim 11, wherein the first branch waveguide has a first inner reflective surface, and the second branch waveguide has a second inner reflective surface, and
wherein the first exit waveguide has a third inner reflective surface, and the second exit waveguide has a fourth inner reflective surface.

14. The optical device of claim 13, wherein the first exit waveguide is inclined from the first branch waveguide such that the first inner reflective surface has a second angle with respect to the third inner reflective surface, and
wherein the second exit waveguide is inclined from the second branch waveguide such that the second inner reflective surface has the second angle with respect to the fourth inner reflective surface.

15. The optical device of claim 11, further comprising:
a coupler on a side portion of the front insulation layer; and
an optical fiber secured by the coupler.

16. A semiconductor package, comprising:
a package substrate including a first mounting region and a second mounting region spaced from the first mounting region in a first direction;
at least one of electronic device mounted on the first mounting region of the package substrate;
a photonic IC chip mounted on the second mounting region of the package substrate, the photonic IC chip including a substrate having a first surface and a second surface opposite the first surface, a front insulation layer on the first surface of the substrate and including a first material having a first index of refraction, and an optical waveguide in the front insulation layer and including a second material having a second index of refraction greater than the first index of refraction, and
an electronic IC chip stacked on the front insulation layer, being spaced apart from the optical waveguide in the first direction, and being electrically connected with the photonic IC chip,
wherein the optical waveguide includes,
an entrance waveguide extending in the first direction;
a first branch waveguide and a second branch waveguide respectively branched from the entrance waveguide and symmetrically extending with respect to an extended central line of the entrance waveguide;
a concave reflector between the first branch waveguide and the second branch waveguide and having a first reflective surface and a second reflective surface symmetrically extending with respect to the extended central line;
a first exit waveguide extending from the first branch waveguide in the first direction; and
a second exit waveguide extending from the second branch waveguide in the first direction,
wherein the first reflective surface is adjacent the first branch waveguide and the second reflective surface is adjacent the second branch waveguide,
wherein the first reflective surface is configured to reflect a first optical signal introduced from the entrance waveguide and to transmit the first optical signal into the second branch waveguide, and
wherein the second reflective surface is configured to reflect a second optical signal introduced from the entrance waveguide and to transmit the first optical signal into the first branch waveguide.

17. The semiconductor package of claim 16, wherein the entrance waveguide includes a first extended reflective surface and a second extended reflective surface facing each other and extending in the first direction,
wherein the first branch waveguide is branched from the entrance waveguide such that a first outer reflective surface of the first branch waveguide has a first angle with respect to the first extended reflective surface, and
wherein the second branch waveguide is branched from the entrance waveguide such that a second outer reflective surface of the second branch waveguide has the first angle with respect to the second extended reflective surface.

18. The semiconductor package of claim 16, wherein the first branch waveguide has a first inner reflective surface, and the second branch waveguide has a second inner reflective surface, and
wherein the first exit waveguide has a third inner reflective surface, and the second exit waveguide has a fourth inner reflective surface.

19. The semiconductor package of claim 18, wherein the first exit waveguide is inclined from the first branch waveguide such that the first inner reflective surface has a second angle with respect to the third inner reflective surface, and
wherein the second exit waveguide is inclined from the second branch waveguide such that the second inner reflective surface has the second angle with respect to the fourth inner reflective surface.

20. The semiconductor package of claim 16, further comprising:
a coupler on a side portion of the front insulation layer; and
an optical fiber secured by the coupler.
